(19) United States
(12) Patent Application Publication
(10) Pub. No.: US 2013/0029451 A1
(43) Pub. Date: Jan. 31, 2013

(54) METHOD FOR MAKING A SOLAR CELL

(71) Applicants: Yu-Lun Chueh, Hsinchu (TW); Chin-Hung Liu, Tainan (TW); Chih-Huang Lai, Hsinchu (TW)

(72) Inventors: Yu-Lun Chueh, Hsinchu (TW); Chin-Hung Liu, Tainan (TW); Chih-Huang Lai, Hsinchu (TW)

(21) Appl. No.: 13/355,822

(22) Filed: Jan. 23, 2012

(30) Foreign Application Priority Data
Jul. 25, 2011 (TW) 100126185

(51) Int. Cl. H01L 31/0272; H01L 31/0264

(52) U.S. Cl. 438/85; 438/95; 257/E31.004; 257/E31.008

(57) ABSTRACT

A method for making a solar cell includes: (a) forming over a substrate a photoelectric transformation layer that is made of a chalcopyrite-based photovoltaic material; (b) performing an ion milling treatment, in which ions are injected to an upper surface of the photoelectric transformation layer at an ion incident angle with respect to the upper surface to partially etch the photoelectric transformation layer, so that the photoelectric transformation layer is formed with a plurality of nano-pillar structures, the ion incident angle ranging from 0° to 90°; and (c) forming an electrode unit to transmit electricity from the photoelectric transformation layer.

### CROSS-REFERENCE TO RELATED APPLICATION

This application claims priority of Taiwanese application no. 100126185, filed on Jul. 25, 2011.

### BACKGROUND OF THE INVENTION

1. Field of the Invention

This invention relates to a method for making a solar cell, more particularly to a method for making a thin film solar cell that includes a photoelectric transformation layer made of a chalcopyrite-based photovoltaic material.

2. Description of the Related Art

A solar cell includes a semiconductor structure having a p-n junction, in which light energy can be converted to electricity by virtue of the photovoltaic effect. In recent years, with the thickness and low-cost requirements for the solar cell, many efforts have been devoted to research and development of the thin film solar cell.

Referring to FIG. 1, a conventional planar-type thin film solar cell 1 includes a substrate 11, a photoelectric transformation layer 12, and an electrode unit 13 that has a lower electrode 131 and an upper electrode 132. The lower electrode 131, the photoelectric transformation layer 12, and the upper electrode 132 are sequentially formed on the substrate 11. Usually, the upper electrode 132 includes a transparent conductive film 134 for guiding carriers, a buffer film 133 formed between the transparent conductive film 134 and the photoelectric transformation layer 12, and an electrode pad 135 for electrically connecting to an external device (not shown). After the light energy is absorbed by the photoelectric transformation layer 12 to produce current due to the generation of electron-hole pairs, the current can be guided to and saved in the external device through the lower and upper electrodes 131, 132.

An important factor for the thin film solar cell is photoelectric transformation efficiency of a material used in the photoelectric transformation layer 12. Recently, examples of the material of the photoelectric transformation layer 12 include amorphous silicon (a-Si), cadmium telluride (CdTe), and a chalcopyrite-based photovoltaic material (Cu(Ga, In)(S, Se)₂). Among the three materials, the chalcopyrite-based photovoltaic material has band gaps covering most of solar spectrum, has a relatively high light absorption coefficient, and is adapted to form a p-n junction by modifying its composition. Therefore, the chalcopyrite-based photovoltaic material for serving as the material of the photoelectric transformation layer 12 has attracted much attention.

Besides, the efficiency of the solar cell can be further enhanced by roughening or patterning a light-incident face of the solar cell to improve the light absorbing ratio of the solar cell. With the roughened or patterned light-incident face, the light-incident possibility and/or the light-absorbing area of the solar cell can be increased. For example, U.S. Pat. Nos. 6,399,177 and 7,605,327, US patent application publication no. 2011/0048528, and Taiwanese application publication no. 200741354 have disclosed processes for roughening or patterning the light-incident face. The processes involve lithography techniques or high density plasma chemical vapor deposition techniques, which are relatively complicated, thereby resulting in higher costs.

### SUMMARY OF THE INVENTION

Therefore, an object of the present invention is to provide a method for making a solar cell that can overcome the aforesaid drawbacks associated with the prior art.

Accordingly, a method for making a solar cell of this invention comprises:
(a) forming over a substrate a photoelectric trans formation layer that is made of a chalcopyrite-based photovoltaic material;
(b) performing an ion milling treatment, in which ions are directed to an upper surface of the photoelectric trans formation layer at an ion incident angle with respect to the upper surface to partially etch the photoelectric transformation layer, so that the photoelectric transformation layer is formed with a plurality of nano-pillar structures, the ion incident angle ranging from 0° to 90°; and
(c) forming an electrode unit that is adapted to transmit electricity from the photoelectric transformation layer.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a fragmentary side view of a conventional thin film solar cell;

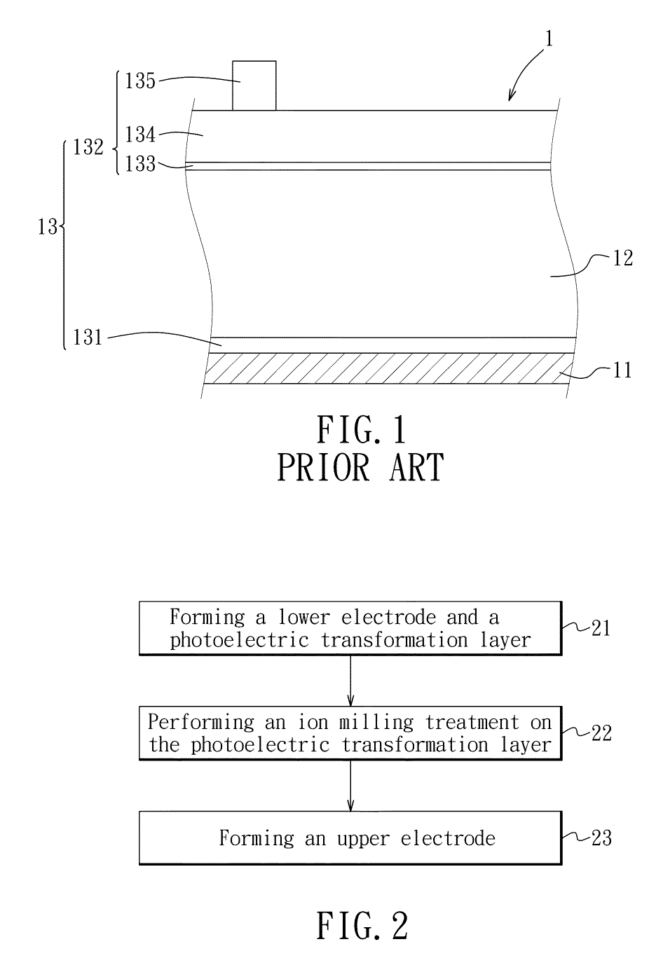

FIG. 2 is a flowchart showing the preferred embodiment of a method for making a thin film solar cell according to this invention;

FIG. 3 is a fragmentary side view of the preferred embodiment of a thin film solar cell according to this invention;

FIGS. 4 to 6 illustrate consecutive steps of the method of FIG. 2;

FIG. 7 is an electron microscopy image of nano-pillar structures which are formed after an ion milling treatment with an ion incident angle of 15°;

FIG. 8 is an electron microscopy image of nano-pillar structures which are formed after an ion milling treatment with an ion incident angle of 45°; and

FIG. 9 is an electron microscopy image of nano-pillar structures which are formed after anion milling treatment with an ion incident angle of 90°.

### DETAILED DESCRIPTION OF THE PREFERRED EMBODIMENTS

Before the present invention is described in greater detail with reference to the accompanying preferred embodiments, it should be noted herein that similar elements are denoted by the same reference numerals throughout the disclosure.

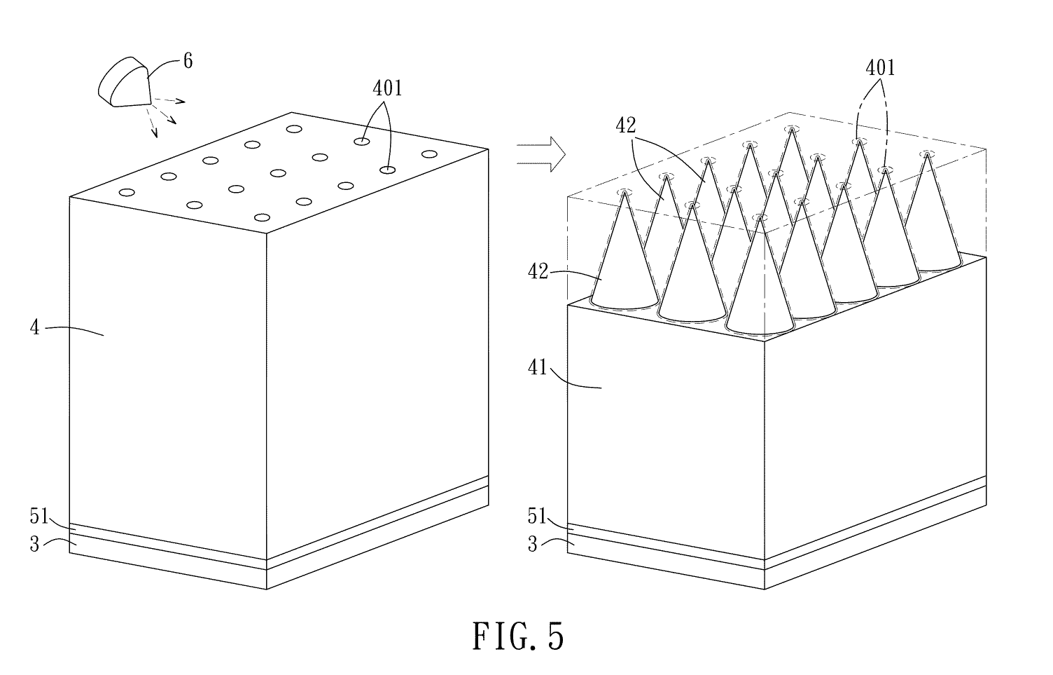

Referring to FIG. 3, the preferred embodiment of a thin film solar cell according to this invention includes a substrate 3, a photoelectric transformation layer 4 that is made of a chalcopyrite-based photovoltaic material, and an electrode unit 5.

The photoelectric transformation layer 4 and the electrode unit 5 are deposited on the substrate 3. Candidate materials for the substrate 3 includes glass, quartz, transparent plastic material, sapphire, flexible material, etc. Presently, the substrate 3 is made of soda-lime glass (SLG), because sodium elements in SLG are likely to diffuse into the chalcopyrite-based photovoltaic material of the photoelectric transformation layer 4, thereby enhancing the photoelectric transformation efficiency.

The photoelectric transformation layer 4 can convert light energy into electricity by virtue of the photovoltaic effect, and includes a main body 41 and a plurality of nano-pillar structures 42 that are formed in a matrix form on the main body 41 oppositely of the substrate 3. Preferably, each of the nano-pillar structures 42 is a nano-cone. Each of the nano-pillar structures 42 has a height ranging from 120 nm to 320 nm, and is inclined with respect to an upper surface of the main body 41 at an angle ranging from 0° to 90°. With the nano-pillar structures 42, the surface area of the photoelectric transformation layer 4 is greatly increased, and the incident light is liable to be multi-reflected among and be absorbed by the nano-pillar structures 42 so as to improve the light-absorbing efficiency of the solar cell.

In this invention, the chalcopyrite-based photovoltaic material (Cu(Ga, In)(Se, Se)₂) is composed of I-III-VI chalcopyrite compounds, and has a long service life due to its anti-jamming and anti-radiation properties. In the preferred embodiment, the photoelectric transformation layer 4 is made of copper indium gallium diselenide (Cu(InₓGa₁₋ₓ)Se₂, 0≦x≦1, CIGS), which is a derivate of copper indium diselenide (CuInSe₂, CIS), and which is formed by substituting gallium elements for some of the indium elements in the CIS material. The absorption bandgap can be controlled by adjusting ratio between indium and gallium content of the chalcopyrite-photovoltaic material. Besides, the CIGS material has better photoelectric transformation efficiency than the CIS material. Examples of the suitable chalcopyrite-based photovoltaic material further include copper indium disulfide (CuInS₂), copper indium gallium disulfide (Cu(InₓGa₁₋ₓ)S₂), copper-indium-gallium-sulfur-selenium (Cu(InₓGa₁₋ₓ)SeS), etc.

The electrode unit 5 includes a lower electrode 51 and an upper electrode 52, and is used to transmit electricity (current), which is induced by the migration of excited electron-hole pairs that are generated in the photoelectric transformation layer 4, to an external device (not shown). In this embodiment, the lower electrode 51 is made of molybdenum (Mo), and is sandwiched between the substrate 3 and the photoelectric transformation layer 4 to make ohmic contact with the photoelectric transformation layer 4. The upper electrode 52 is formed on the photoelectric transformation layer 4 oppositely of the substrate 3, and includes a buffer layer 521, a transparent conductive layer 522, and an electrode pad 533. The buffer layer 521 covers over the photoelectric transformation layer 4, and is normally made of cadmium sulfide-based (CdS-based) material. The transparent conductive layer 522 is deposited on the buffer layer 521, and is made of transparent conductive oxide (TCO) in which aluminum-doped zinc oxide or indium tin oxide (ITO) is preferable. The electrode pad 533 is formed on the transparent conductive layer 522, and is made of aluminum or other conductive metal materials. The materials and the purpose of the electrode unit 5 are well-known in the solar cell industry, and detail descriptions are omitted herein.

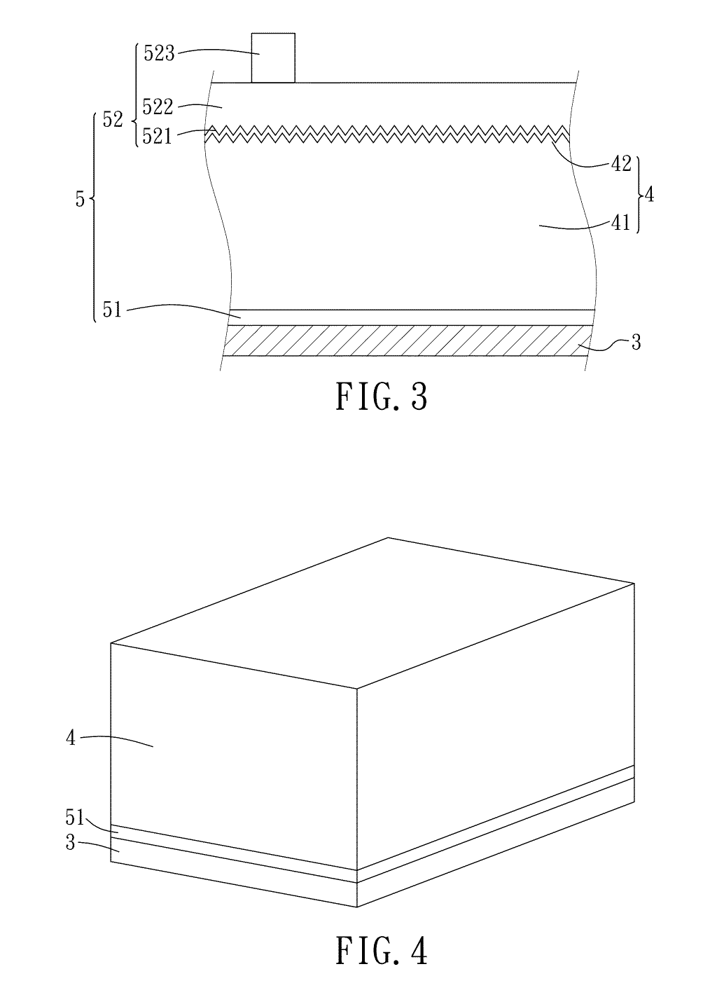

The present invention is explained in more details below as a method for making the thin film solar cell (see FIGS. 2 and 3) according to this invention. The method includes following steps.

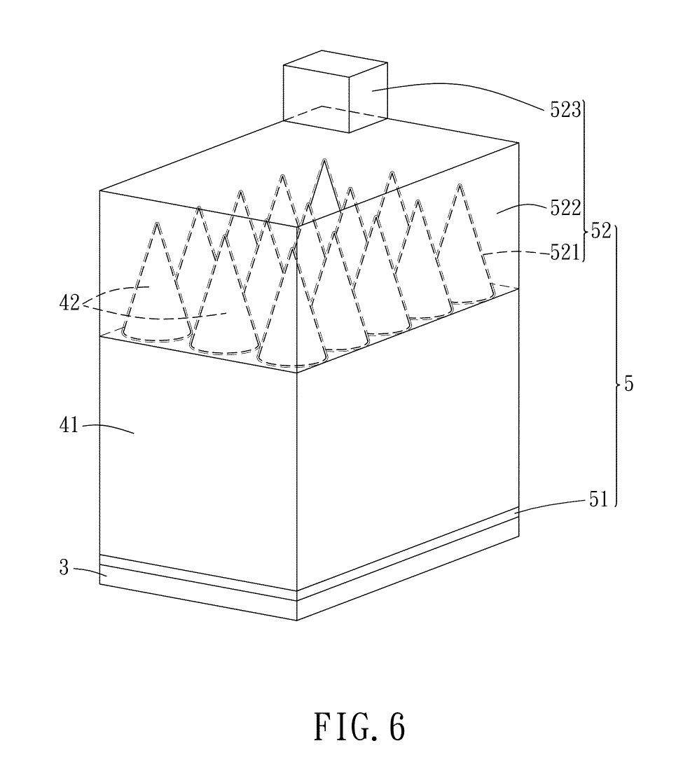

Referring to FIG. 4, in step 21, the lower electrode 51 is formed over the substrate 3 by pulse DC magnetron sputtering a molybdenum layer, and the photoelectric transformation layer 4, which made of CIGS material, is formed by multi-sputtering-target techniques. The substrate 3 is made of soda-lime glass.

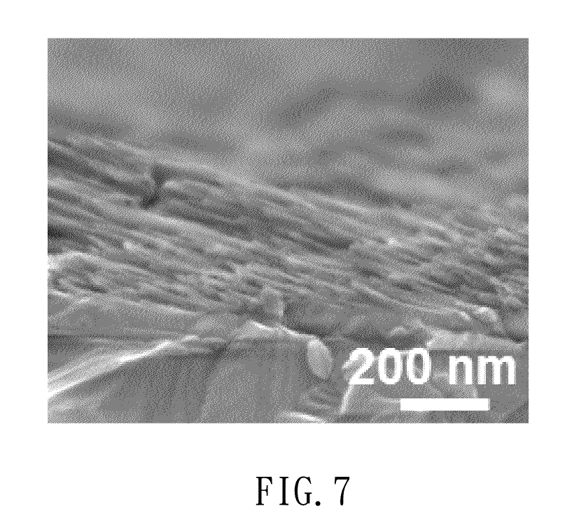

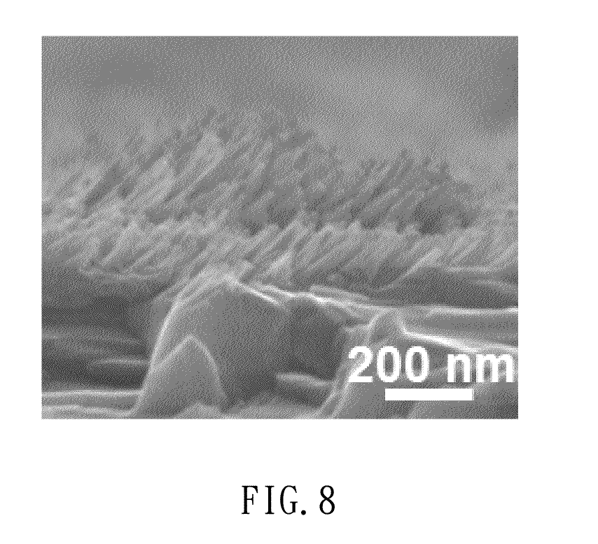

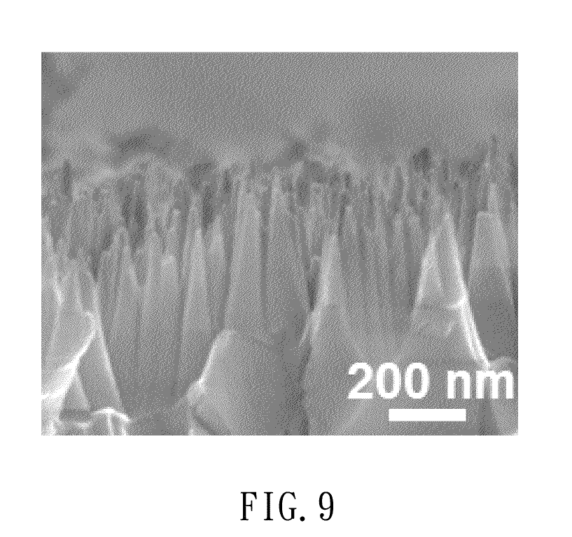

In step 22, an ion milling treatment is performed using an ion milling system 6 (see FIG. 5). In the ion milling treatment, ions (Ar ions) are directed to an upper surface of the photoelectric transformation layer 4 at an incident angle with respect to the upper surface to partially etch and to modify the photoelectric transformation layer 4, so that the photoelectric transformation layer 4 is formed into the main body 41 and the nano-pillar structures 42. The ion incident angle ranges from 0° to 90°. During the ion milling treatment, copper elements in the CIGS material segregate to the upper surface to form a plurality of separated copper segregations 401 on the upper surface of the photoelectric transformation layer 4. The separated copper segregations 401 are distributed in a density not less than 4.5×10¹³ per square centimeter, are in nano-scale, and inhibit the etching of the photoelectric transformation layer 4 so as to form the nano-pillar structures 42. Each of the nano-pillar structures 42 has a height ranging from 120 nm to 320 nm and is inclined with respected to an upper surface of the main body 41 by an angle ranging from 0° to 90° (see also FIGS. 7 to 9). The nano-pillar structures 42 are also dispersed in a density not less than 4.5×10¹³ per square centimeter, and thus, the surface area of the photoelectric transformation layer 4 can be greatly increased.

In step 23, the upper electrode 52 is formed (see FIG. 6). Specifically, the buffer layer 521 is formed over the photoelectric transformation layer 4 using, for example, chemical bath deposition (CBD), and has a relatively small thickness for passage of light. Then, the transparent conductive layer 522 is formed over the buffer layer 521 using an RF magnetron sputter. The material of the transparent conductive layer 522 may be zinc oxide doped with aluminum or other material that can reduce electrical resistance. Finally, the electrode pad 523 is formed over the transparent conductive layer 522 using an e-gun evaporation system. The electrode pad 523 is made of aluminum or other conductive metals. After this step, the electrode unit 5 is formed, and the solar cell is obtained.

With the nano-pillar structures 42, the surface area of the photoelectric transformation layer 4 is greatly increased, and light is unlikely to be directly reflected by the photoelectric transformation layer 4, thereby enhancing the light-absorbing efficiency of the solar cell of this invention. Besides, because the copper elements segregate among themselves during the ion milling treatment, the nano-pillar structures 42 are formed without using lithography technique. Accordingly, the method of this invention is simple and low-cost.

In addition, from the following Table 1, it is known that the element ratio difference of the copper elements between the main body 41 and top ends of the nano-pillar structures 42 becomes larger with the treating time of the ion milling treatment. Therefore, the inventors of this application speculate that the copper elements segregate to inhibit the etching of the photoelectric transformation layer 4 during the ion milling treatment.

TABLE 1

| Treating | | | | | |
|---|---|---|---|---|---|
| time | Element ratio | | | | |
| (minutes) | (%) | Cu | In | Ga | Se |
| 0 | Nano-pillar | 27.46 | 19.49 | 9.11 | 43.77 |
| | structure | | | | |
| | (Top end) | | | | |
| | Main body | 24.6 | 17.88 | 13.07 | 44.45 |
| 10 | Nano-pillar | 35.6 | 17.61 | 8.1 | 38.69 |
| | structure | | | | |
| | (Top end) | | | | |
| | Main body | 22.94 | 15.77 | 7.39 | 53.9 |
| 20 | Nano-pillar | 50.94 | 6.14 | 10.45 | 32.46 |
| | structure | | | | |
| | (Top end) | | | | |
| | Main body | 25.14 | 10.23 | 7.7 | 56.93 |
| 60 | Nano-pillar | 50.5 | 8.96 | 7.45 | 33.1 |
| | structure | | | | |
| | (Top end) | | | | |
| | Main body | 24.32 | 19.56 | 8.76 | 47.35 |

While the present invention has been described in connection with what are considered the most practical and preferred embodiments, it is understood that this invention is not limited to the above-mentioned embodiments but is applicable to cover various arrangements included within the spirit and scope of the broadest interpretations and equivalent arrangements.

What is claimed is:

1. A method for making a solar cell, comprising:
(a) forming over a substrate a photoelectric trans formation layer that is made of a chalcopyrite-based photovoltaic material;
(b) performing an ion milling treatment, in which ions are directed to an upper surface of the photoelectric transformation layer at an incident angle with respect to the upper surface to partially etch the photoelectric transformation layer, so that the photoelectric transformation layer is formed with a plurality of nano-pillar structures, the incident angle ranging from 0° to 90°; and
(c) forming an electrode unit that is adapted to transmit electricity from the photoelectric transformation layer.

2. The method of claim 1, wherein the chalcopyrite-based photovoltaic material is selected from the group consisting of copper indium diselenide (CuInSe₂), copper indium gallium diselenide (Cu(InₓGa₁₋ₓ)Se₂), copper indium disulfide (CuInS₂), copper indium gallium disulfide (Cu(InₓGa₁₋ₓ)S₂), copper-indium-gallium-sulfur-selenium (Cu(InₓGa₁₋ₓ)SeS), and combinations thereof.

3. The method of claim 1, wherein, in step (b), copper elements in the chalcopyrite-based photovoltaic material segregate to the upper surface to form a plurality of separated copper segregations on the upper surface of the photoelectric transformation layer, the separated copper segregations inhibiting the etching of the photoelectric transformation layer so as to form the nano-pillar structures.

4. The method of claim 3, wherein each of the nano-pillar structures has a height ranging from 120 nm to 320 nm.

5. The method of claim 3, wherein the separated copper segregations are distributed in a density not less than 4.5×10¹³ per square centimeter.

6. The method of claim 1, wherein the ions are Ar ions.
